(19) United States
(12) Patent Application Publication
(10) Pub. No.: US 2024/0088221 A1
(43) Pub. Date: Mar. 14, 2024

(54) SEMICONDUCTOR DEVICE

(71) Applicant: FUJI ELECTRIC CO., LTD., Kanagawa (JP)

(72) Inventor: Kaname MITSUZUKA, Matsumoto-city (JP)

(21) Appl. No.: 18/513,685

(22) Filed: Nov. 20, 2023

Related U.S. Application Data
(63) Continuation of application No. PCT/JP2022/039617, filed on Oct. 25, 2022.

(30) Foreign Application Priority Data
Dec. 27, 2021 (JP) 2021-212821

(51) Int. Cl. H01L 29/08; H01L 29/06; H01L 29/417; H01L 29/739

(52) U.S. Cl. CPC H01L 29/0804; H01L 29/0696; H01L 29/41708; H01L 29/7397

(57) ABSTRACT

A semiconductor device includes: a gate trench portion provided in a semiconductor substrate; a first trench portion provided in the semiconductor substrate and adjacent to the gate trench portion; an emitter region of a first conductivity type provided to be in contact with the gate trench portion in a mesa portion between the gate trench portion and the first trench portion; a contact region of a second conductivity type provided to be in contact with the first trench portion in the mesa portion; a metal layer provided above the semiconductor substrate; and a resistance portion of the first conductivity type provided to be in contact with the metal layer and the emitter region and having a lower doping concentration than that of the emitter region.

The contents of the following patent application(s) are incorporated herein by reference:
NO. 2021-212821 filed in JP on Dec. 27, 2021
NO. PCT/JP2022/039617 filed in WO on Oct. 25, 2022

### BACKGROUND

### 1. Technical Field

The present invention relates to a semiconductor device.

### 2. Related Art

Patent Literature 1 describes “improving characteristics such as saturation current in semiconductor devices”.

### PRIOR ART LITERATURE

### Patent Literature

Patent Literature 1: Japanese Patent Application Publication No. 2018-195798
Patent Literature 2: WO2018/052098

### BRIEF DESCRIPTION OF THE DRAWINGS

FIG. 1A illustrates a top view of a semiconductor device 100.

FIG. 1B is an example of a-a′ cross sectional view in FIG. 1A.

FIG. 1C is an example of b-b′ cross sectional view in FIG. 1A.

FIG. 2 illustrates an example of an enlarged cross sectional view of a mesa portion 71.

FIG. 3 illustrates an example of a simulation result of a current-voltage curve when the resistance portion is provided.

FIG. 4A illustrates an example of a top view of a semiconductor device 100.

FIG. 4B is an example of g-g′ cross sectional view in FIG. 4A.

FIG. 5 illustrates an example of an enlarged cross sectional view of a mesa portion 71.

FIG. 6A illustrates an example of a top view of the semiconductor device 100.

FIG. 6B is an example of h-h′ cross sectional view in FIG. 6A.

FIG. 7A illustrates an example of a top view of a semiconductor device 100.

FIG. 7B is an example of j-j′ cross sectional view in FIG. 7A.

FIG. 8A illustrates an example of a top view of the semiconductor device 100.

FIG. 8B is an example of k-k′ cross sectional view in FIG. 8A.

### DESCRIPTION OF EXEMPLARY EMBODIMENTS

Hereinafter, the present invention will be described through embodiments of the present invention, but the following embodiments do not limit the present invention according to claims. In addition, not all combinations of features described in the embodiment are essential to the solution of the invention.

In the present specification, one side in a direction parallel to a depth direction of a semiconductor substrate is referred to as an “upper” side, and the other side is referred to as a “lower” side. One surface of two principal surfaces of a substrate, a layer, or other member is referred to as a front surface, and the other surface is referred to as a back surface. “Upper”, “lower”, “front”, and “back” directions are not limited to a direction of gravity, or a direction of an attachment to a substrate or the like when a semiconductor device is mounted.

In the present specification, technical matters may be described using orthogonal coordinate axes of an X axis, a Y axis, and a Z axis. In the present specification, the X-Y plane is the plane parallel to the front surface of the semiconductor substrate, and the Z axis is the direction that forms a right-handed system with the X axis and Y axis and is parallel to the depth direction of the semiconductor substrate.

Each example embodiment shows an example in which a first conductivity type is set as an N type, and a second conductivity type is set as a P type; however, the first conductivity type may be the P type, and the second conductivity type may be the N type. In this case, conductivity types of the substrate, the layer, a region, and the like in each example embodiment respectively have opposite polarities.

In the present specification, a character N or P specifying a layer or a region means that electrons or holes are majority carriers, respectively. Also, ‘+’ and ‘−’ attached on ‘N’ and ‘P’ respectively mean that the higher doping concentration and the lower doping concentration than the layer or region to which these symbols are not attached. In addition, the doping concentration means a net impurity concentration represented by a difference between a donor concentration and an acceptor concentration.

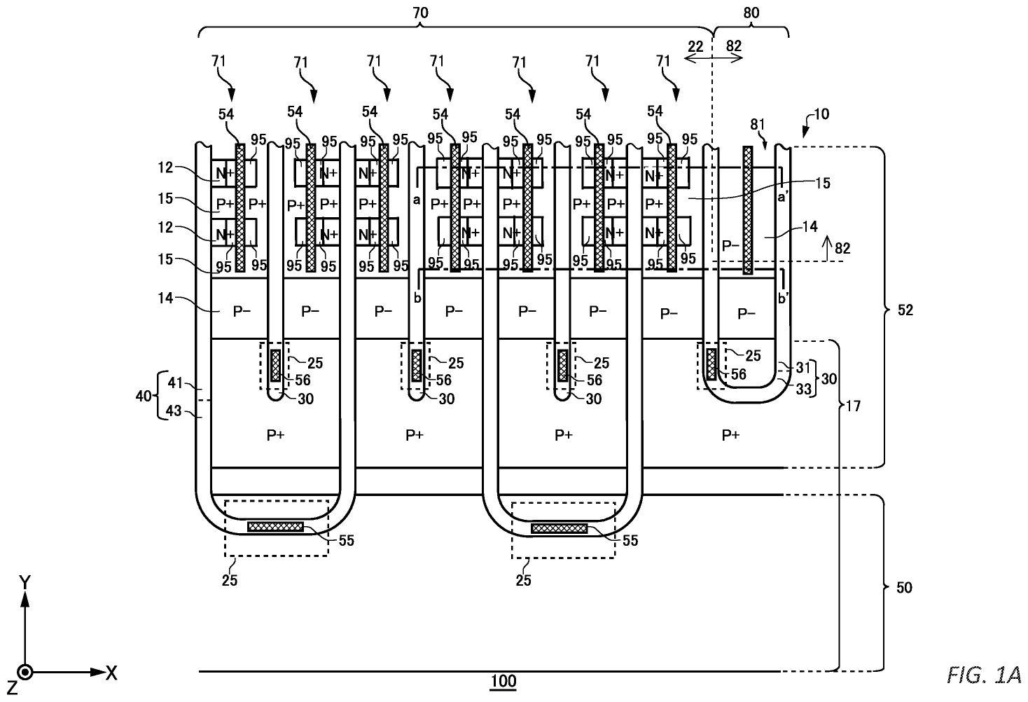

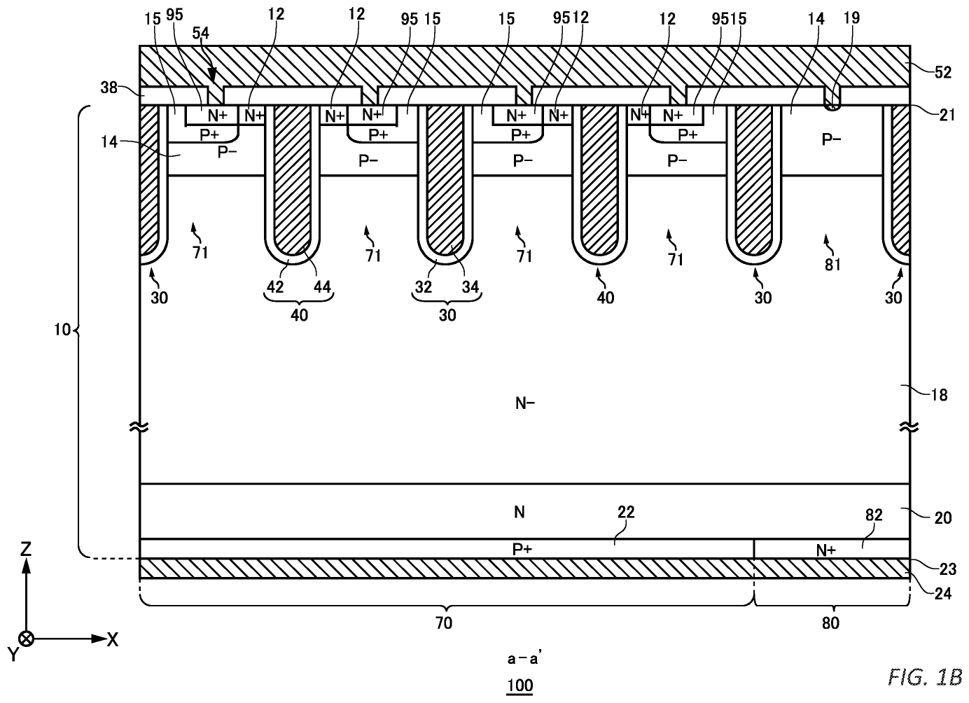

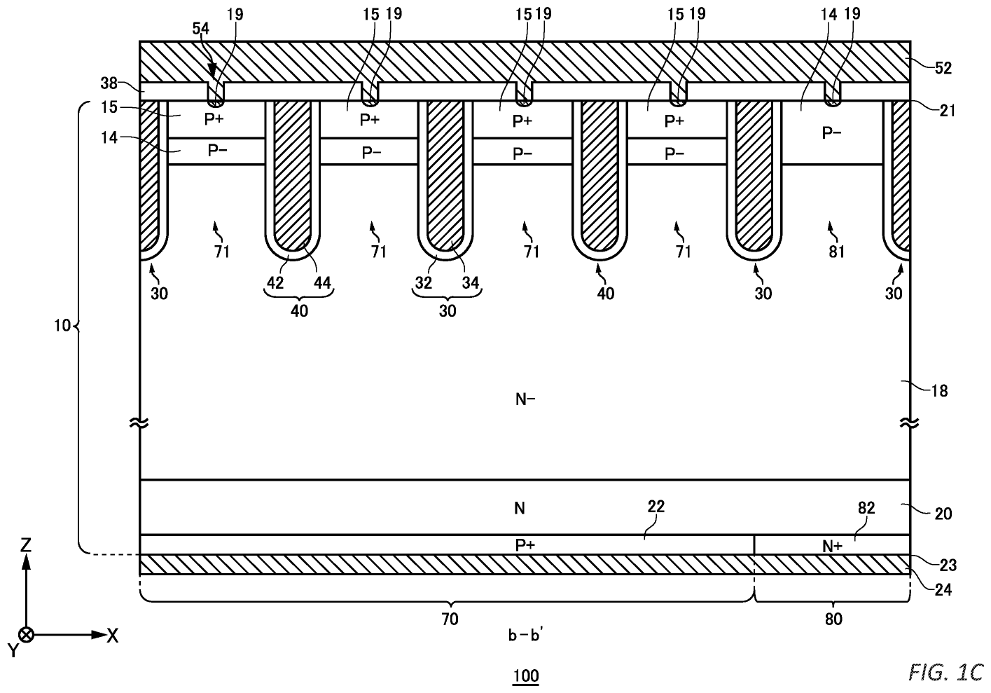

FIG. 1A illustrates an example of the top view of a semiconductor device 100. The semiconductor device 100 of the present example is a semiconductor chip including a transistor portion 70 and a diode portion 80. For example, the semiconductor device 100 is a trench gate type RC-IGBT (Reverse Conducting Insulated Gate Bipolar Transistor) in which a plurality of trench portions are arrayed. In the present example, the plurality of trench portions are in a striped pattern in which the trench portions are arrayed in the X axis direction and extend in the Y axis direction.

The transistor portion 70 is a region in which a collector region 22 provided on the back surface side of the semiconductor substrate 10, as will be described below in FIG. 1B, is projected onto the front surface of the semiconductor substrate 10. The collector region 22 has the second conductivity type. The collector region 22 in the present example is of the P+ type as an example. The transistor portion 70 includes transistors such as IGBTs.

The diode portion 80 is a region in which a cathode region 82 provided on the back surface side of the semiconductor substrate 10, as will be described below in FIG. 1B, is projected onto the front surface of the semiconductor substrate 10. The cathode region 82 has the first conductivity type. The cathode region 82 in the present example is of the N+ type as an example. The diode portion 80 includes a diode such as a free wheel diode (FWD) provided being adjacent to the transistor portion 70 at the upper surface of the semiconductor substrate 10.

FIG. 1A illustrates a surrounding region of a chip end portion, which is an edge side of the semiconductor device 100, and the other regions are omitted. For example, an edge termination structure portion is provided in the region on the negative side of the Y axis direction in the semiconductor device 100 in the present example. The edge termination structure portion is to relax an electric field strength in the upper surface side of the semiconductor substrate 10. The edge termination structure portion includes, for example, a guard ring, a field plate, an RESURF structure, and combinations thereof. Note that although the present example describes the edge in the negative side in the Y axis direction for convenience, the same applies to other edges of the semiconductor device 100.

The semiconductor substrate 10 may be a silicon substrate, may be a silicon carbide substrate, or may be a nitride semiconductor substrate such as gallium nitride, or the like. The semiconductor substrate 10 in the present example is a silicon substrate.

The semiconductor device 100 of the present example includes a gate trench portion 40, a dummy trench portion 30, an emitter region 12, a base region 14, a contact region 15, and a well region 17, on the front surface of the semiconductor substrate 10. Also, the semiconductor device 100 of the present example includes an emitter electrode 52 and a gate metal layer 50, which are provided above the front surface of the semiconductor substrate 10.

The emitter electrode 52 is provided above the gate trench portion 40, the dummy trench portion 30, the emitter region 12, the base region 14, the contact region 15, and the well region 17. In addition, the gate metal layer 50 is provided above the gate trench portion 40 and the well region 17.

The emitter electrode 52 and the gate metal layer 50 are formed of a material including metal. For example, at least a part of a region of the emitter electrode 52 is formed of aluminum, an aluminum-silicon alloy, or an aluminum-silicon-copper alloy. At least a part of a region of the gate metal layer 50 may be formed of aluminum, aluminum-silicon alloy, or an aluminum-silicon-copper alloy. The emitter electrode 52 and the gate metal layer 50 may include a barrier metal formed of titanium, titanium compound, or the like, which underlies a region formed of aluminum or the like. The emitter electrode 52 and the gate metal layer 50 are provided separately from each other.

The emitter electrode 52 and the gate metal layer 50 are provided above the semiconductor substrate 10 to sandwich an interlayer dielectric film 38. The interlayer dielectric film 38 is omitted in FIG. 1A. A contact hole 54, a contact hole 55, and a contact hole 56 are provided through the interlayer dielectric film 38.

The contact hole 55 is connected to the gate metal layer 50 and the gate conductive portion inside the gate trench portion 40 of the transistor portion 70. Inside the contact hole 55, a plug formed of tungsten or the like may be formed.

The contact hole 56 connects the emitter electrode 52 with a dummy conductive portion in a dummy trench portion 30. Inside the contact hole 56, a plug formed of tungsten or the like may be formed.

The connection portion 25 electrically connects a front surface side electrode such as the emitter electrode 52 or the gate metal layer 50 to the semiconductor substrate 10. In an example, the connection portion 25 is provided between the gate metal layer 50 and the gate conductive portion. The connection portion 25 is also provided between the emitter electrode 52 and the dummy conductive portion. The connection portion 25 is formed of a conductive material such as polysilicon doped with impurities. Here, the connection portion 25 is formed of polysilicon (N+) doped with the impurities of the N type. The connection portion 25 is provided above the front surface of the semiconductor substrate 10 via a dielectric film such as an oxide film, or the like.

The gate trench portions 40 are arrayed in a predetermined interval along a predetermined trench arrangement direction (the X axis direction in the present example). As an example, although the gate trench portions 40 are arrayed in a trench interval of 1.5 μm, the trench interval is not limited to this interval. The gate trench portion 40 in the present example may have two extending portions 41 extending along the trench extending direction perpendicular to the trench arrangement direction and parallel to the front surface of the semiconductor substrate 10 (Y axis direction in the present example), and a connection portion 43 for connecting the two extending portions 41.

At least a part of the connection portion 43 is preferably formed in a curved shape. When the end portions of the two extending portions 41 of the gate trench portion 40 are connected to each other, the electric field strength at the end portions of the extending portions 41 can be reduced. At the connection portion 43 of the gate trench portion 40, the gate metal layer 50 may be connected to the gate conductive portion.

The dummy trench portion 30 in the present example is connected electrically to the emitter electrode 52, and is a trench portion set at the emitter potential. The dummy trench portions 30 are, similarly to the gate trench portions 40, arrayed in a predetermined interval along a predetermined trench arrangement direction (the X axis direction in the present example). As an example, although the dummy trench portions 30 are arrayed in a trench interval of 1.5 μm, the trench interval is not limited to this interval. In particular, the trench interval of the dummy trench portions 30 may be provided to be different from the trench interval of the gate trench portions 40. The dummy trench portion 30 in the present example may also have a U-shape on the front surface of the semiconductor substrate 10, similarly to the gate trench portion 40. That is, the dummy trench portion 30 may have two extending portions 31 extending along the trench extending direction, and connection portions 33 to connect the two extending portions 31. The dummy trench portion 30 may be regarded as the floating potential. The dummy trench portion 30 is an example of the first trench portion adjacent to the gate trench portion 40.

The transistor portion 70 in the present example has a structure repeatedly arraying two gate trench portions 40 with the connection portion 43 and two dummy trench portions 30 without the connection portion. That is, the array ratio of the gate trench portion 40 to the dummy trench portion 30 may be set as a predetermined desired array ratio. In the transistor portion 70 in the present example, the ratio of the number of the gate trench portions 40 to the number of the dummy trench portions 30 is 1:1. The transistor portion 70 in the present example has a dummy trench portion 30 between the two extending portions 41 connected to the connection portion 43. Note that the number of the gate trench portions 40 may be the number of the extending portions 41. The number of the dummy trench portions 30 may be the number of the extending portions 31.

That is, in the present example, the gate trench portions 40 and the dummy trench portions 30 are alternately arranged in the trench arrangement direction. Thus, in the present example, the trench portion adjacent to the gate trench portion 40 refers to the dummy trench portion 30. In another example, the trench portion adjacent to the gate trench portion 40 may also be the gate trench portion set at the gate potential or may also be a dummy gate trench portion set at the gate potential and being not in contact with the emitter region, not only the dummy trench portion 30 set at the emitter potential.

It is noted however that the ratio of the gate trench portions 40 and the dummy trench portions 30 is not limited to the present example. The ratio between the gate trench portions 40 and the dummy trench portions 30 may be 2:3 or may be 2:4. By increasing the number of the dummy trench portions 30 with respect to the gate trench portion 40, the electric field strength in the mesa portion can be reduced, and the withstand capability of the voltage and the current of the semiconductor device 100 can be increased. Also, by adjusting the ratio of the gate trench portion 40 to the dummy trench portion 30, the gate capacitance for driving the semiconductor device 100 can be adjusted. With respect to the gate trench portion 40, by increasing the number of the dummy trench portion 30, the gate capacitance is increased, and the saturation current is decreased. Also, in the transistor portion 70, the dummy trench portion 30 is not provided, and the so-called full gate structure, in which all the trench portions are gate trench portions 40, is also possible. Note that the ratio of the gate trench portion 40 and the dummy trench portion 30 disclosed herein may be replaced with the ratio of the gate trench portion 40 and a dummy trench. The dummy trench includes a trench without a channel formed at the side wall, like the dummy trench portion 30.

The well region 17 is a region of a second conductivity type provided in the front surface side of the semiconductor substrate 10 than the drift region 18, which will be described below. The well region 17 is an example of the well region provided in the edge side of the semiconductor device 100. The well region 17 is of the P+ type as an example. The well region 17 is formed within a predetermined range from an end portion of the active region in a side in which the gate metal layer 50 is provided. A diffusion depth of the well region 17 may be deeper than depths of the gate trench portion 40 and the dummy trench portion 30. Partial regions of the gate trench portion 40 and the dummy trench portion 30 in the gate metal layer 50 side are formed in the well region 17. The bottoms of the trench extending direction ends of the gate trench portions 40 and the dummy trench portions 30 may be covered by the well region 17.

The contact hole 54 is formed above each region of the emitter region 12 and the contact region 15 in the transistor portion 70. The emitter region 12 and contact region 15 are exposed in the contact hole 54. The contact hole 54 is not provided above the well region 17 provided at both ends of the Y axis direction. In this manner, one or more contact holes 54 are formed in the interlayer dielectric film. One or more contact holes 54 may be provided to extend in the trench extending direction.

The mesa portion 71 and the mesa portion 81 are mesa portions provided adjacent to the trench portion in the surface parallel to the front surface of the semiconductor substrate 10. The mesa portion may be a portion of the semiconductor substrate 10 sandwiched by two trench portions that are adjacent to each other, and may be a portion from the front surface of the semiconductor substrate 10 down to the depth of the bottom portion, which is the deepest portion, of each trench portion. The extending portions of each trench portion may be regarded as one trench portion. That is, the region sandwiched between two extending portions may be set to be a mesa portion.

The mesa portion 71 is provided adjacent to at least one of the dummy trench portion 30 or the gate trench portion 40 in the transistor portion 70. The mesa portion 71 includes the well region 17, the emitter region 12, the base region 14, the contact region 15, and a resistance portion 95 on the front surface of the semiconductor substrate 10.

On the other hand, the mesa portion 81 is provided adjacent to the dummy trench portion 30 in the diode portion 80. The trench portion in the diode portion 80 may be electrically connected to the emitter electrode 52 through the contact hole 56 to be set at the emitter potential. That is, the trench portion provided in the diode portion 80 may be the dummy trench portion 30.

The mesa portion 81 includes the well region 17 and the base region 14 on the front surface of the semiconductor substrate 10. Note that the emitter electrode 52 is also arranged above the mesa portion 81. That is, the metal layer of the emitter electrode 52 may function as an anode electrode in the diode portion 80.

The base region 14 is the region of the second conductivity type provided in the front surface side of the semiconductor substrate 10 in the transistor portion 70. The base region 14 is of the P− type as an example. The base region 14 may be provided at both end portions of the mesa portion 71 in the Y axis direction, in the front surface of the semiconductor substrate 10. Note that FIG. 1A illustrates only one end portion in the Y axis direction of the base region 14. The base region 14 may also be provided in the diode portion 80.

The emitter region 12 is a region of the first conductivity type which has a higher doping concentration than that of the drift region which will be described below in FIG. 18. The emitter region 12 in the present example is of the N+ type as an example. For example, the dopant of the emitter region 12 is phosphorus (P) or arsenic (As) or the like. The emitter region 12 is provided to be in contact with the gate trench portion 40 in the mesa portion 71. The emitter region 12 is provided to extend in the trench arrangement direction from the gate trench portion 40 to the resistance portion 95.

The resistance portion 95 is the region of the first conductivity type provided on the front surface of the semiconductor substrate 10 in the transistor portion 70. The resistance portion 95 in the present example is of, as an example, the N+ type. The doping concentration of the resistance portion 95 is lower than the doping concentration of the emitter region 12. The resistance portion 95 is provided to be in contact with the end of the emitter region 12 at the dummy trench portion 30 side. As will be described below referring to FIG. 1B, the resistance portion 95 is also provided below the contact hole 54.

The contact region 15 is a region of the second conductivity type having a higher doping concentration than that of the base region 14. The contact region 15 in the present example is of the P+ type as an example. An example of the dopant of the contact region 15 is boron (B). The contact region 15 in the present example is provided to be in contact with the dummy trench portion 30 in the mesa portion 71. The contact region 15 may be provided to extend in the trench arrangement direction from one trench portion to the other trench portion of two trench portions, where the mesa portions 71 are interposed between the respective trench portions and the dummy trench portion 30

Note that, as will be described below referring to FIG. 1B, the contact region 15 may terminate not to reach the dummy trench portion 30 to be spaced apart from the gate trench portion 40 at a portion in which the emitter region 12 is provided. The contact region 15 is also provided below the contact hole 54. Note that the contact region 15 may be provided in the mesa portion 81.

FIG. 1B illustrates an example of the a-a′ cross sectional view in FIG. 1A. The a-a′ cross section is a X-Z plane passing through the emitter region 12 and the resistance portion 95 in the transistor portion 70. In the cross section a-a′, the semiconductor device 100 in the present example has the semiconductor substrate 10, the interlayer dielectric film 38, the emitter electrode 52, and a collector electrode 24. The emitter electrode 52 is formed above the semiconductor substrate 10 and the interlayer dielectric film 38.

The emitter electrode 52 is provided on the front surface 21 of the semiconductor substrate 10 and an upper surface of the interlayer dielectric film 38. The emitter electrode 52 is electrically connected to the front surface 21 through the contact hole 54 of the interlayer dielectric film 38. A plug (not shown in the figure) made of tungsten (W) or the like may be embedded inside the contact hole 54 via a barrier metal film. Note that the metal such as the emitter electrode 52, and the plug and the barrier metal embedded inside the contact hole 54 may collectively be referred to as a metal layer.

The interlayer dielectric film 38 is provided at the front surface 21. The emitter electrode 52 is provided above the interlayer dielectric film 38. In the interlayer dielectric film 38, one or more contact holes 54 are provided for electrically connecting the emitter electrode 52 to the semiconductor substrate 10. Similarly, the contact hole 55 and the contact hole 56 may be provided to pass through the interlayer dielectric film 38.

The drift region 18 is a region of the first conductivity type which is provided in the semiconductor substrate 10. The drift region 18 in the present example is of the N− type as an example. The drift region 18 may be a region that has remained without other doping regions being formed in the semiconductor substrate 10. That is, the doping concentration of the drift region 18 may be a doping concentration of the semiconductor substrate 10.

A buffer region 20 is a region of the first conductivity type provided below the drift region 18. The buffer region 20 in the present example is of the N type as an example. The doping concentration of the buffer region 20 is higher than the doping concentration of the drift region 18. The buffer region 20 may function as a field stop layer which prevents a depletion layer spreading from the lower surface side of the base region 14 from reaching the collector region 22 of the second conductivity type and the cathode region 82 of the first conductivity type.

The collector region 22 is provided below the buffer region 20 in the transistor portion 70. The collector electrode 24 is formed on the back surface 23 of the semiconductor substrate 10. The collector electrode 24 is formed of a conductive material such as metal.

The base region 14 is a region of the second conductivity type provided above the drift region 18 in the mesa portion 71 and the mesa portion 81. The base region 14 is provided in contact with the gate trench portion 40. The base region 14 may be provided in contact with the dummy trench portion 30.

The emitter region 12 is provided above the base region 14 in the mesa portion 71. The emitter region 12 is provided to be in contact with the gate trench portion 40. The emitter region 12 in the present example may or may not be in contact with the dummy trench portion 30. The emitter region 12 in the present example is spaced apart from the dummy trench portion 30. In addition, the emitter region 12 in the present example is not exposed to the bottom surface of the contact hole 54.

The resistance portion 95 has a side wall provided to be in contact with the emitter region 12 and a lower end provided to be in contact with the contact region 15. The resistance portion 95 is provided to be in contact with the contact hole 54. The resistance portion 95 in the present example extends from the end of the emitter region 12 to the dummy trench portion 30 side beyond the contact hole 54. The resistance portion 95 is electrically connected to the emitter electrode 52 via the contact hole 54. That is, the emitter electrode 52 and the emitter region 12 are in contact via the resistance portion 95, but not directly in contact. In the present example, the side wall of the resistance portion 95 opposite to the side in contact with the emitter region 12 is in contact with the contact region 15.

The contact region 15 is provided to extend beyond the contact hole 54 from the dummy trench portion 30 in the trench arrangement direction. The contact region 15 in the present example is provided to be spaced apart from the gate trench portion 40. Therefore, the contact region 15 does not prevent the inversion layer from being formed on the side wall of the gate trench portion 40 to allow the stable operation of the semiconductor device 100 to. In addition, the contact region 15 is provided to be deeper than the resistance portion 95 and in contact with the resistance portion 95 at the upper surface.

The contact region 15 in the present example is provided to extend from the dummy trench portion 30 to both sides thereof in the trench arrangement direction. In the fabrication process of the contact region 15 in the present example, a resist may be provided on the semiconductor substrate 10, and ions may be implanted to provide the contact region 15 which extends across a region in which a trench portion is to be provided. The dummy trench portion 30 may be provided by performing etching on the semiconductor substrate 10 after the contact region 15 is provided.

Recently, for the purpose of miniaturization of the semiconductor device 100 or the like, namely miniaturization of the process pitch has been in progress, that is, a width of the mesa portion 71 is shortened. For example, when diffusion regions are provided by ion implantation in a silicon semiconductor substrate 10, dopants tend to diffuse within a certain range. The structure of the contact region 15 in the present example facilitates fabrication of the contact region 15 spaced apart from the gate trench portion 40, even if the process pitch is miniaturized. This can provide semiconductor devices 100 with high latch-up withstand capability without significantly affecting electrical characteristics.

One or more gate trench portions 40 and one or more dummy trench portions 30 are provided at the front surface 21. Each trench portion is provided from the front surface 21 to the drift region 18. In regions being provided with at least any of the emitter region 12, the base region 14 and the contact region 15, each trench portion penetrates these regions and reaches the drift region 18. The configuration of the trench portion penetrating through the doping region is not limited to that manufactured in the order of forming the doping region and then forming the trench portion. The configuration of the trench portion passing through the doping region includes a configuration of the doping region being formed between the trench portions after forming the trench portion.

The gate trench portion 40 has a gate trench, a gate dielectric film 42, and a gate conductive portion 44 which are formed in the front surface 21. The gate dielectric film 42 is formed to cover an inner wall of the gate trench. The gate dielectric film 42 may be formed by oxidizing or nitriding a semiconductor on the inner wall of the gate trench. The gate conductive portion 44 is formed more inner than the gate dielectric film 42 inside the gate trench. The gate dielectric film 42 insulates the gate conductive portion 44 from the semiconductor substrate 10. The gate conductive portion 44 is formed of a conductive material such as polysilicon. The gate trench portion 40 is covered by the interlayer dielectric film 38 in the front surface 21. The potential at the gate metal layer such as IGBT is applied to the gate conductive portion 44.

The gate conductive portion 44 includes a region opposing the adjacent base region 14 in the mesa portion 71 side by sandwiching the gate dielectric film 42 in a depth direction of the semiconductor substrate 10. When a predetermined voltage is applied to the gate conductive portion 44, a channel as an inversion layer of electrons is formed in the interfacial surface layer of the base region 14 in contact with the gate trench.

The dummy trench portion 30 may have the same structure as the gate trench portion 40. The dummy trench portion 30 has a dummy trench, a dummy dielectric film 32, and a dummy conductive portion 34 which are formed in the front surface 21 side. The dummy dielectric film 32 is formed covering the inner walls of the dummy trench. The dummy conductive portion 34 is formed inside the dummy trench and also formed more inner than the dummy dielectric film 32. The dummy dielectric film 32 insulates the dummy conductive portion 34 from the semiconductor substrate 10. The dummy trench portion 30 is covered by the interlayer dielectric film 38 in the front surface 21. The potential at the emitter electrode such as IGBT is applied to the dummy conductive portion 34. The dummy conductive portion 34 may be a floating potential.

In the diode portion 80, the buffer region 20 is provided above the cathode region 82 and the drift region 18 is provided above the buffer region 20. In the mesa portion 81, the base region 14 is provided above the drift region 18 such that the P-N junction is formed between the base region 14 and the drift region 18. The base region 14 is electrically connected to the emitter electrode 52 via the contact hole 54.

FIG. 1C is an example of the b-b′ cross sectional view in FIG. 1A. The b-b′ cross section is an X-Z plane which does not pass through emitter region 12 and the resistance portion 95 in the transistor portion 70. In the present example, the mesa portion 71 in the transistor portion 70 has a base region 14 and a contact region 15 above the drift region 18. The mesa portion 81 has a structure similar to the example in the FIG. 1B in the diode portion 80.

The contact region 15 in the b-b′ cross section is different from the contact region 15 provided below the resistance portion 95 and extends from the gate trench portion 40 to the dummy trench portion 30. The contact holes 54 are provided above the contact region 15. The hole is extracted from the contact region 15 via the contact holes 54.

When the contact region 15 provided below the resistance portion 95 and the contact region 15 in the b-b′ cross section are provided in the same process, these contact regions 15 are provided to have the same depth. In this case, the contact region 15 is provided to be deeper than the emitter region 12. Note that the contact region 15 may be provided to have a depth in a region below the emitter region 12 different from a depth in another region.

A plug region 19 of the P+ type is provided below the contact hole 54, having a doping concentration higher than that of the contact region 15. The plug region 19 in the present example is provided on the front surface 21 of the semiconductor substrate 10. The plug region 19 may be provided in a region below the contact hole 54 and above the contact region 15. The lower end of the plug region 19 may be provided to be shallower than the lower end of the contact region 15. The hole is extracted from the contact region 15 and the plug region 19 via the contact hole 54. The plug region 19 improves the contact resistance between the barrier metal of the contact hole 54 and the contact region 15 to increase the latch up withstand capability.

The plug region 19 may be provided in a region below the contact hole 54 and above the base region 14. The plug region 19 may be provided in the mesa portion 71 and may be provided in the mesa portion 81. The plug region 19 may not be provided in a region below the contact hole 54 and above the emitter region 12. In this case, the plug regions 19 may be discretely provided along the contact hole 54 to correspond to the repeated structure of the emitter regions 12 and the contact regions 15 in the mesa portion 71, and may be provided to extend in the Y axis direction along the contact hole 54 in the mesa portion 81.

Alternatively, the plug region 19 may also be provided in a region below the contact hole 54 and above the emitter region 12. In this case, the plug region 19 may be provided to extend in the Y axis direction along the contact hole 54 in the mesa portion 71 and the mesa portion 81. The lower end of the plug region 19 may be provided to be shallower than the lower end of the emitter region 12.

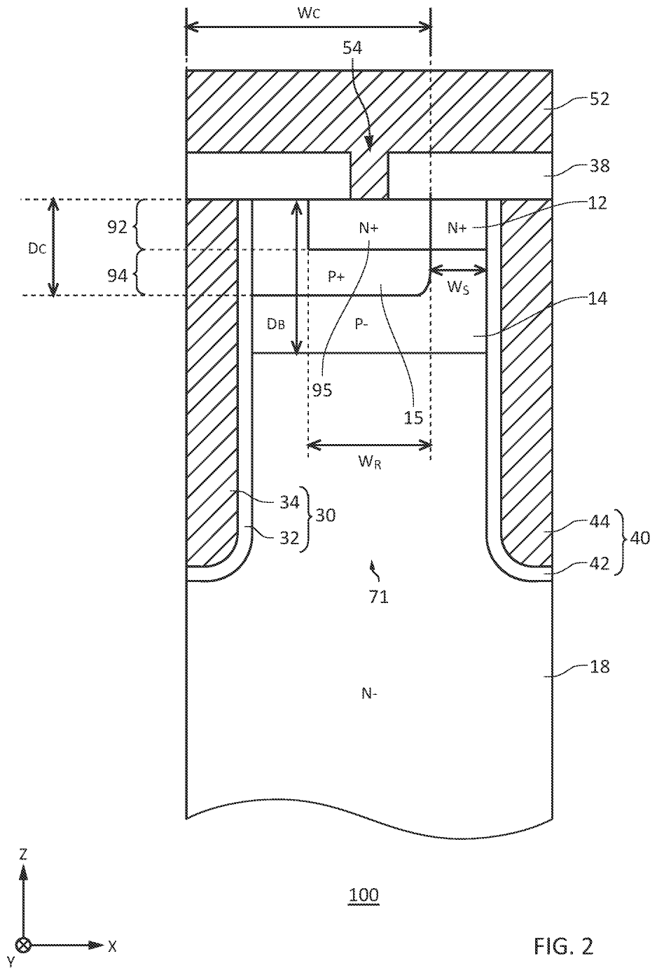

FIG. 2 illustrates an example of an enlarged cross sectional view of the mesa portion 71. In the present example, the X-Z plane which passes the emitter region 12 and the resistance portion 95 in the transistor portion 70 is illustrated. FIG. 2 schematically illustrates a cross section of the contact hole 54 as a rectangular shape, but not limited thereto. The cross section of the contact hole 54 may also be a stepped shape or a tapered shape with the side walls tilted. In such a case, a distance between the contact hole 54 and another element which will be described below may be an average distance or may be a shortest distance from a representative point.

The emitter region 12 extends in the trench arrangement direction from the gate trench portion 40 to the resistance portion 95. The resistance portion 95 extends from the end of the emitter region 12 to the dummy trench portion 30 side beyond the contact hole 54. The resistance portion 95 in the present example is spaced apart from the dummy trench portion 30, while the resistance portion 95 in another example may be provided to be in contact with the dummy trench portion 30. In the trench arrangement direction, the width W R of the resistance portion 95 is 5 to 25% of the width of the mesa portion 71. The emitter region 12 and the resistance portion 95 in the present example have the same depth in the semiconductor substrate 10.

The doping concentration of the resistance portion 95 is equal to or smaller than the doping concentration of the emitter region 12. The doping concentration of the resistance portion 95 is equal to or greater than 5E17 cm⁻³ and equal to or smaller than 2E18 cm⁻³. When the emitter region 12 and the resistance portion 95 are formed in the same process, the resistance portion 95 may also be a region in contact with the contact region 15 at its lower end.

The resistance portion 95 may include a region which has a doping concentration increasing from the end of the dummy trench portion 30 side to the end of the gate trench portion 40 side. When the emitter region 12 and the resistance portion 95 are formed in the same process, the dopants diffuse from the gate trench portion 40 side in a lateral direction to form the emitter region 12 and the resistance portion 95. Thus, a region spaced apart from the gate trench portion 40, that is, a region of the resistance portion 95 in contact with the contact hole 54, has a varied doping concentration, and the doping concentration is lower in a region closer to the contact hole 54.

The resistance portion 95 is in contact with the contact region 15 at its lower end so that a part of the donors are neutralized to relatively lower the doping concentration. Thus, the resistance value of the resistance portion 95 is higher than the resistance value of the emitter region 12 not in contact with the contact region 15.

Note that the resistance value of the entire emitter region 12 may be increased by reducing the amount of the dopants implanted in the emitter region 12, which may suppress generation of carriers itself and prevent electron currents even if the voltage is applied. Therefore, in the present embodiment, the resistance portion 95 is provided between the emitter region 12 and the contact hole 54 having a doping concentration lower than that of the emitter region 12.

In this manner, the resistance portion 95 provided between the emitter region 12 and the contact hole 54 has a relatively high resistance value to function as a restricting resistance when a large amount of currents flow to suppress electron currents, thereby improving the short circuit withstand capability of the semiconductor device 100.

The contact region 15 includes a surface region 92 and a lower region 94 below the surface region 92. The surface region 92 is a region exposed to the front surface 21 of the semiconductor substrate 10 and having the same depth as those of the emitter region 12 and the resistance portion 95. In the present example, the resistance portion 95 is interposed between the emitter region 12 and the surface region 92 in the trench arrangement direction. The depth of the surface region 92 is 0.5 μm as an example. Note that the depth of the surface region 92 may be provided at a different depth. The surface region 92 is not provided when the emitter region 12 is provided to extend from the gate trench portion 40 to the dummy trench portion 30 across the mesa portion 71. In addition, the doping concentration of the surface region 92 may be in a range of equal to or greater than 5E19 cm⁻³ and equal to or smaller than 2E20 cm⁻³.

The lower region 94 is provided in a region below the surface region 92 and deeper than the emitter region 12. The lower region 94 extends to the gate trench portion 40 side beyond the end of the emitter region 12 at the gate trench portion 40 side in the trench arrangement direction. In addition, the doping concentration of the lower region 94 may be in a range of equal to or greater than 1E19 cm⁻³ to equal to or smaller than 1E20 cm⁻³.

The width Wc is a width of the contact region 15 in the trench arrangement direction. The width Wc is a distance from the center of the dummy trench portion 30 to the end of the emitter region 12 at the gate trench portion 40 side (that is, the end of the lower region 94 at the gate trench portion 40 side). The width Wc may be equal to or greater than 1.2 μm, and may be equal to or smaller than 1.1 μm. Here, the width of the surface region 92 in the trench arrangement direction may be in a range of equal to or greater than 15% and equal to or smaller than 40% of the distance of the neighboring trenches (that is, the center-to-center distance of the trench portions). The width of the lower region 94 in the trench arrangement direction may be in a range from 30% to 70% for the distance between the adjacent trenches. In addition, in the trench arrangement direction, a width of a portion of the lower region 94 which overlaps the emitter region 12 may be in a range of equal to or greater than 0% and equal to or smaller than 30% of the distance between the neighboring trenches, and more preferably, may be in a range of equal to or greater than 10% and equal to or smaller than 20%.

The thickness Dc is a distance in the depth direction of the semiconductor substrate 10 from the front surface of the semiconductor substrate 10 to the lower end of the contact region 15 (that is, the lower end of the lower region 94). The thickness Dc is larger than the thickness of the emitter region 12 and smaller than the thickness D_{B} of the base region 14. For example, the thickness Dc is from 0.5 μm to 2.0 μm. The thickness of the surface region 92 may be in a range from 0.3 μm to 0.8 μm. In addition, the thickness of the lower region 94 may be in a range from 0.3 μm to 1.1 μm.

The width Ws is a width of the emitter region 12 in the trench arrangement direction. That is, the width Ws corresponds to a distance of space between the contact region 15 or the resistance portion 95 and the gate trench portion 40. The width Ws is 0.1 μm or more. The width Ws may be equal to or greater than 0.6 μm. The width Ws may be in a range of equal to or greater than 10% and equal to or smaller than 50% of the distance between the neighboring trenches.

The contact region 15 and the gate trench portion 40 are spaced apart from each other by the width Ws below the emitter region 12 not to prevent a channel from being formed on the side wall of the gate trench portion 40.

In addition, the width Ws may be almost the same as the width W_{R} of the resistance portion 95. In this manner, the resistance portion 95 having a relatively high resistance value is provided to extend almost the same distance as that of the emitter region 12 in the trench arrangement direction to suppress electron currents when a large amount of currents flow and improve the short circuit withstand capability of the semiconductor device 100.

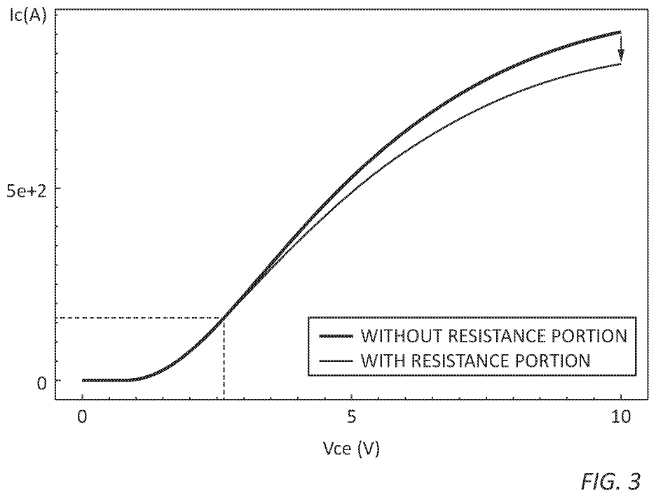

FIG. 3 illustrates an example of a simulation result of a current-voltage curve when the resistance portion is provided. The thick solid line is a simulation result of a current-voltage (Ic-Vce) curve of a conventional semiconductor device not provided with a resistance portion and the thin solid line is that of the semiconductor device provided with the resistance portion described referring to FIG. 1A to FIG. 2.

For the smaller current equal to or smaller than the rated current of the chip indicated by dashed lines, approximately no difference is seen in the Ic-Vce, depending on whether the resistance portion is provided. On the other hand, for the large current exceeding the rated current of the chip, the curve of the thin solid line varies below the curve of the thick solid line as the voltage Vce increases, from which it can be seen that the current Ice of the semiconductor device provided with the resistance portion is suppressed.

In this manner, the resistance portion is provided to suppress about 10% of the short circuit current when the short circuit occurs to improve the short circuit withstand capability. In addition, for the current equal to or smaller than the rated current, a difference in the Ic-Vce depending on whether the resistance portion is provided is small such that the resistance portion can be provided without increasing the ON voltage.

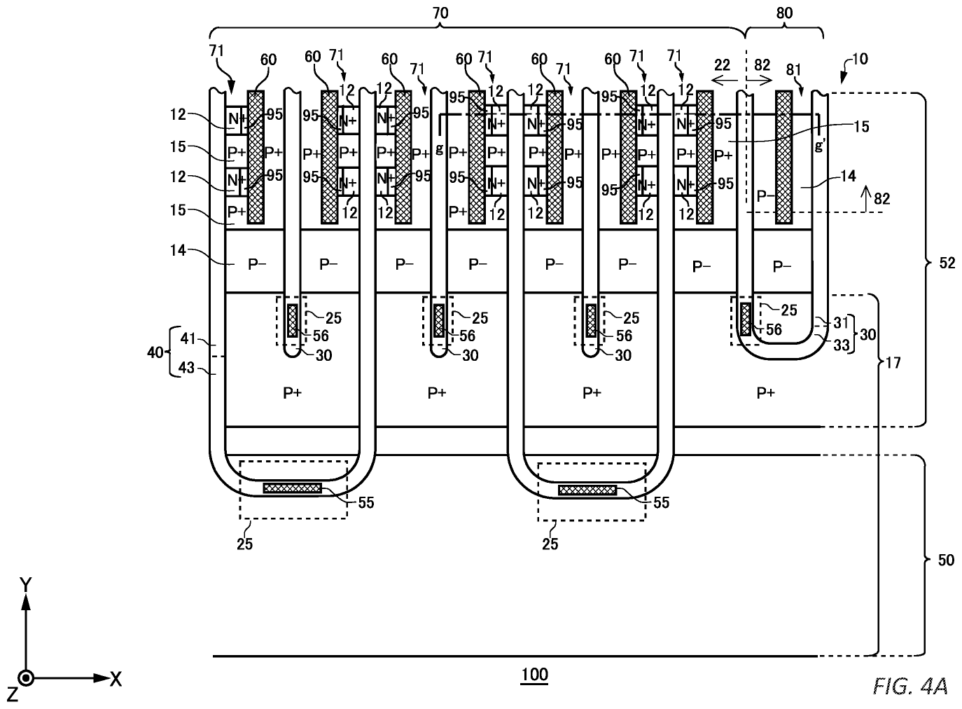

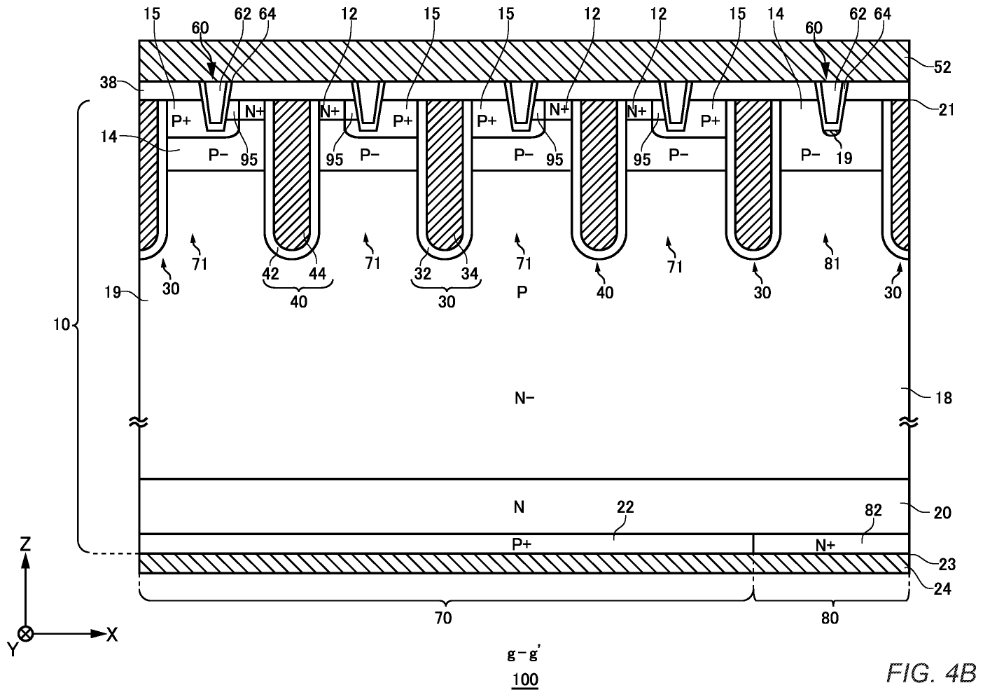

FIG. 4A illustrates an example of the top view of a semiconductor device 100. The semiconductor device 100 in the present example includes a contact trench portion 60.

The contact trench portion 60 is provided to extend in the depth direction of the semiconductor substrate 10 from the front surface 21 in the mesa portion 71 and the mesa portion 81. The contact trench portion 60 electrically connects the emitter electrode 52 and the semiconductor substrate 10. Note that the contact trench portions 60 are continuously provided at the same locations as the contact holes 54 of FIG. 1A to FIG. 3 in a top view of the semiconductor substrate 10. The contact trench portions 60 illustrated in this figure and subsequent figures are to include the contact hole 54 for simplification. The contact trench portion 60 is provided to extend in the trench extending direction in a top view of the semiconductor substrate 10. The contact trench portion 60 in the present example is arranged in a striped shape along the gate trench portion 40 and the dummy trench portion 30.

The contact trench portion 60 is formed above each region of the resistance portion 95 and the contact region 15 in the transistor portion 70. The contact trench portion 60 is formed above the region of the base region 14 in the diode portion 80. The contact trench portion 60 is not provided above the well regions 17, which are provided on both ends of the Y axis direction.

In the mesa portion 71 between the gate trench portion 40 and the contact trench portion 60, the emitter regions 12 or the resistance portions 95 and the contact region 15 may be arranged alternately in the trench extending direction. In the trench extending direction, the widths of the emitter region 12 and the resistance portion 95 may be greater than the width of the contact region 15. In the trench extending direction, the widths of the emitter region 12 and the resistance portion 95 may be equal to or greater than 0.6 μm and equal to or smaller than 1.6 μm. The ratio of the emitter region 12 or the resistance portion 95 and the contact region 15 is controlled as appropriate to facilitate to suppress the latch-up.

The emitter region 12 is provided to be in contact with the gate trench portion 40. The resistance portion 95 is provided to extend in the trench arrangement direction from the end of the emitter region 12 to the side wall of the contact trench portion 60. The resistance portion 95 may not be provided between the dummy trench portion 30 and the contact trench portion 60.

The contact region 15 is provided to be in contact with the dummy trench portion 30. Similarly to FIG. 1A to FIG. 3, the contact region 15 terminates below the resistance portion 95 to be spaced apart from the gate trench portion 40 in a region provided with the emitter region 12 and the resistance portion 95, and extends to the gate trench portion 40 across the mesa portion 71 in a region not provided with the emitter region 12 and the resistance portion 95.

FIG. 4B is an example of the g-g′ cross sectional view in FIG. 4A. The contact trench portion 60 in the present example is provided to extend from the front surface 21 of the semiconductor substrate 10 to the back surface 23 side of the semiconductor substrate 10, compared to the emitter region 12 and the resistance portion 95, to be in contact with the contact region 15 at its lower end. That is, the lower end of the contact trench portion 60 in the present example is deeper than the lower ends of the emitter region 12 and the resistance portion 95. The lower end of the contact trench portion 60 in the present example is shallower than the lower end of the contact region 15.

The emitter region 12 extends in a direction from the gate trench portion 40 to the contact trench portion 60 in the trench arrangement direction to be in contact with the side wall of the resistance portion 95. The resistance portion 95 is provided to extend to the side wall of the contact trench portion 60. That is, in the present example, the resistance portion 95 and the contact region 15 are exposed to the inner surface of the contact trench portion 60 while the emitter region 12 is not exposed. Thus, the emitter region 12 is connected to the emitter electrode 52 via the resistance portion 95 and the contact trench portion 60.

The contact trench portion 60 includes a conductive material filled within the contact hole 54. The contact trench portion 60 may include the same material as the emitter electrode 52. A barrier metal layer 64 formed of titanium, titanium compound or the like may be provided inside the contact trench portion 60 and the contact hole 54. Further, a plug 62 formed of tungsten or the like may be provided inside the contact trench portion 60 and the contact hole 54 via the barrier metal layer 64.

Similarly to FIG. 1B, the plug region 19 may be provided below the contact hole 54. The plug region 19 in the present example is provided to be in contact with the lower end of the contact trench portion 60. The plug region 19 may be provided in the mesa portion 71 and may be provided in the mesa portion 81. The plug region 19 may be provided in a region below the contact hole 54 and above the base region 14. The plug region 19 may not be provided in a region below the contact hole 54 and above the emitter region 12. In this case, the plug regions 19 may be discretely provided along the contact trench portion 60 to correspond to the repeated structure of the emitter regions 12 and the contact regions 15 in the mesa portion 71, and may be provided to extend in the Y axis direction along the contact trench portion 60 in the mesa portion 81.

Alternatively, the plug region 19 may also be provided in a region below the contact hole 54 and above the emitter region 12. In this case, the plug region 19 may be provided to extend in the Y axis direction along the contact trench portion 60 in the mesa portion 71 and the mesa portion 81. The lower end of the plug region 19 may be provided within the contact region 15 or may be provided within the base region 14.

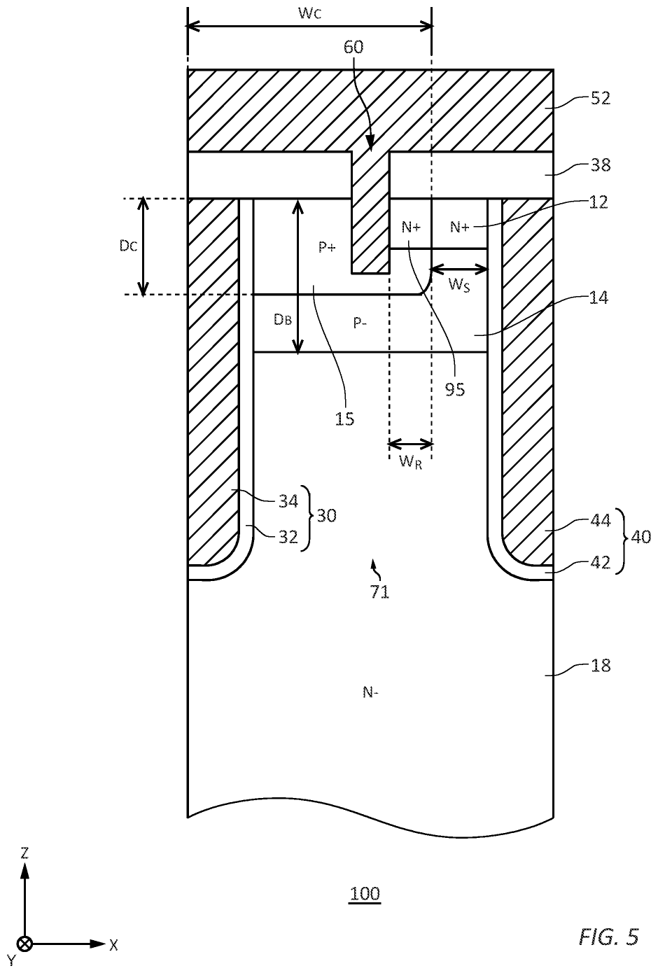

FIG. 5 illustrates an example of an enlarged cross sectional view of the mesa portion 71. In the present example, the X-Z plane which passes the emitter region 12 and the resistance portion 95 in the transistor portion 70 is illustrated. FIG. 5 schematically illustrates a cross section of the contact trench portion 60 as a rectangular shape, but not limited thereto. The cross section of the contact trench portion 60 may also be a stepped shape or a tapered shape with the side walls tilted. In such a case, a distance between the contact trench portion 60 and another element which will be described below may be an average distance or may be a shortest distance from a representative point. Note that the width Wc, the width W_{R}, the width Ws, the thickness Dc or the like are the same as those illustrated in FIG. 2 and also have the same numerical ranges, and therefore the descriptions are omitted.

For example, the contact trench portion 60 is formed by etching the interlayer dielectric film 38. The lower end of the contact trench portion 60 is deeper than the lower ends of the emitter region 12 and the resistance portion 95. Providing the contact trench portion 60 can reduce the resistance of the base region 14 and facilitate minority carriers (for example, holes) to be extracted. This can improve the breakdown withstand capability such as a latch up withstand capability due to minority carriers.

The resistance portion 95 in the present example is provided to be interposed between the emitter region 12 and the side wall of the contact trench portion 60 in the trench arrangement direction. The contact region 15 extends in the trench arrangement direction from the dummy trench portion 30 beyond the lower end of the contact trench portion 60 to be in contact with the resistance portion 95 at its upper surface at the gate trench portion 40 side compared to the contact trench portion 60.

In this manner, the resistance portion 95 in the present example is in contact with the side wall of the contact trench portion 60 to less affect the contact length even if the valiance of the alignment or the size occurs in the forming process. Then, this contacting region is in contact with the contact region 15 at its lower end in the uniform manner to suppress the valiance of the contact resistance so that the semiconductor device 100 having electrically stable characteristics can be provided.

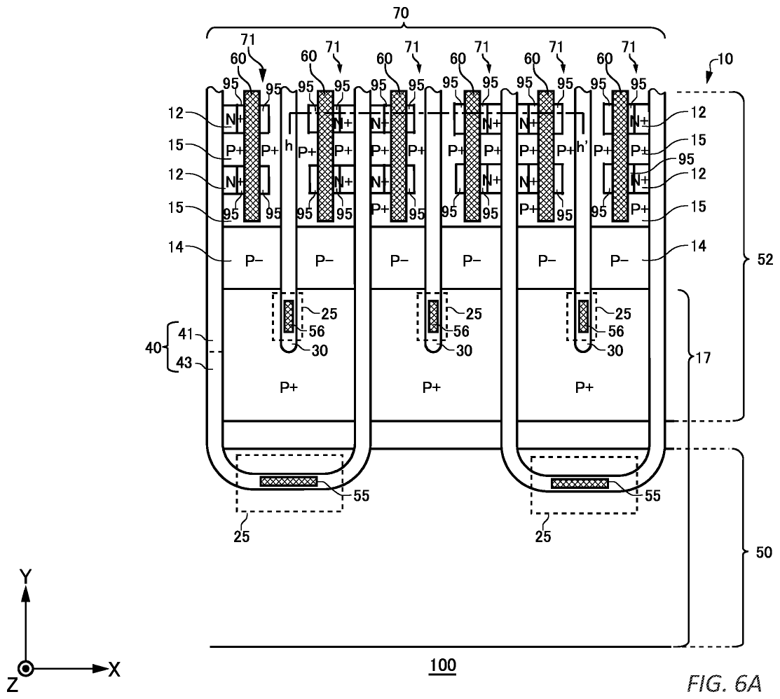

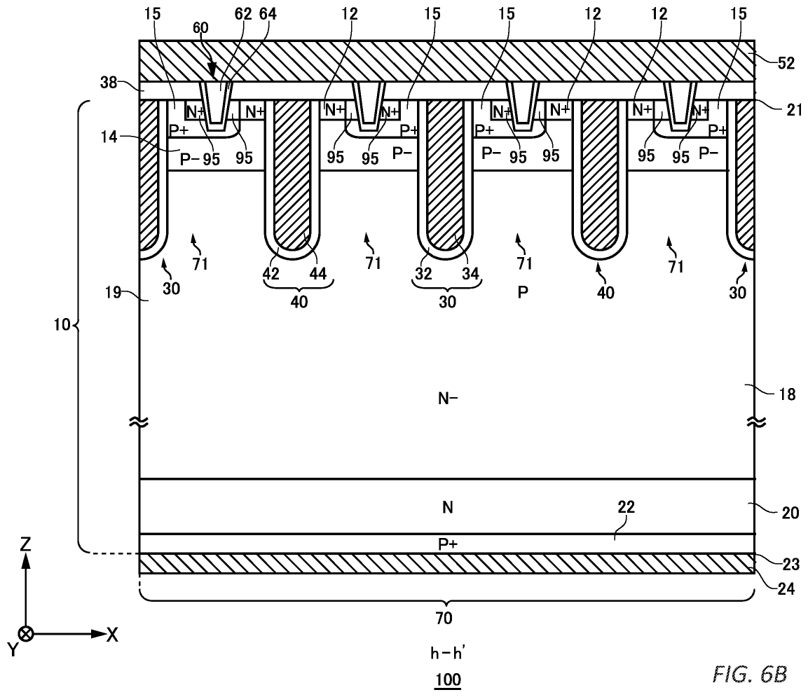

FIG. 6A illustrates an example of the top view of the semiconductor device 100. FIG. 6B is an an example of the h-h′ cross sectional view in FIG. 6A. Here, a difference from FIG. 4A and FIG. 4B will be described.

The resistance portion 95 in the present example is further provided between the side wall of the contact trench portion 60 and the dummy trench portion 30 in the trench arrangement direction. The resistance portion 95 in the present example is spaced apart from the dummy trench portion 30, while the resistance portion 95 in another example may be provided to extend to the dummy trench portion 30. The contact region 15 extends in the trench arrangement direction from the dummy trench portion 30 beyond the lower end of the contact trench portion 60 to also be in contact with the resistance portion 95 at its upper surface at the dummy trench portion 30 side compared to the contact trench portion 60.

In this manner, even when the resistance portion 95 is provided from the end of the emitter region 12 beyond the side wall of the contact trench portion 60 to the dummy trench portion 30 side, the similar effects can be obtained as those of FIG. 4A and FIG. 4B. In addition, when the resistance portion 95 is provided to extend to the dummy trench portion 30, the emitter region 12 and the resistance portion 95 can be formed in the same process and by using a mask with a simple pattern.

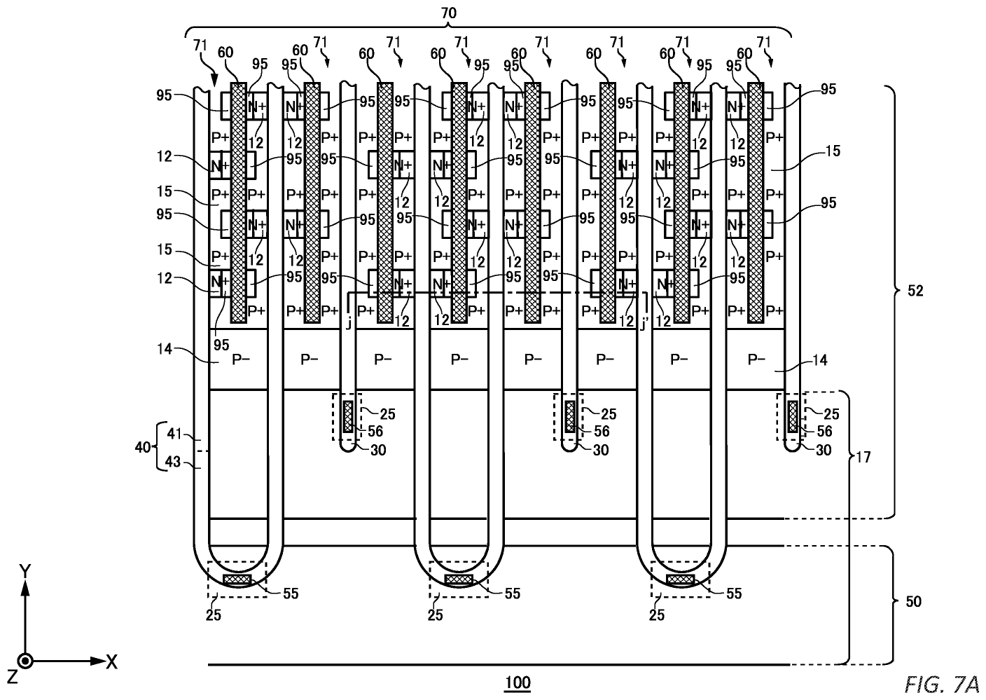

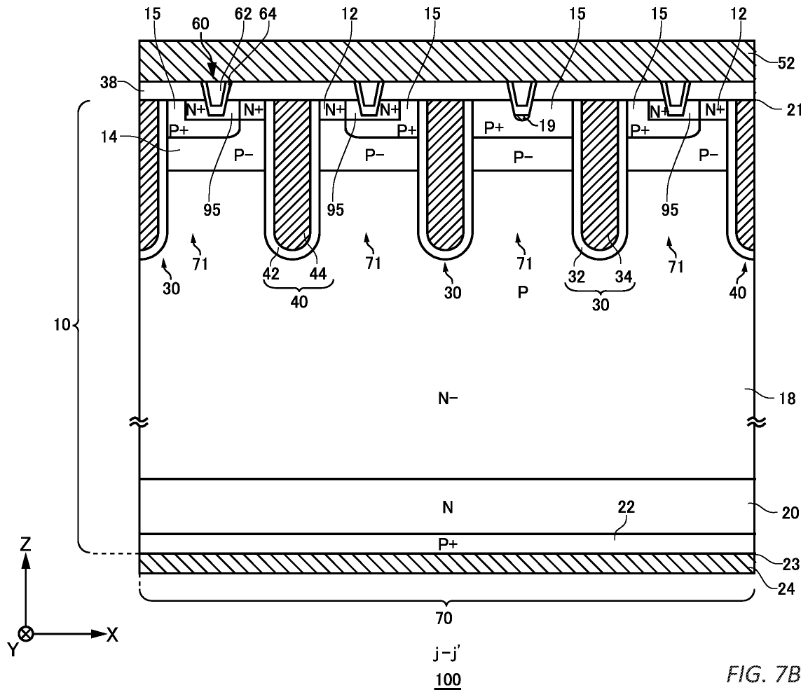

FIG. 7A illustrates an example of the top view of a semiconductor device 100. In the semiconductor device 100 in the present example, the ratio of the number of the gate trench portions 40 and the number of the dummy trench portions 30 in the transistor portion 70 is 2:1. Therefore, the trench portion adjacent to the gate trench portion 40 may be the dummy trench portion 30 or the gate trench portion 40. In addition, the semiconductor device 100 has a staggered structure of the emitter regions 12 alternately arranged. In addition, the semiconductor device 100 includes the contact trench portion 60.

A plurality of gate trench portions 40 provided to be adjacent to one another are in contact with the emitter regions 12 at different locations in the trench extending direction. That is, the semiconductor device 100 includes the emitter regions 12 of the staggered structure which are arranged alternately. Each emitter region 12 is provided to be in contact with the resistance portion 95 having the similar configuration to those of FIG. 6A and FIG. 6B.

In the present example, the emitter region 12 in contact with one gate trench portion 40 (first emitter region) and the emitter region 12 in contact with the other gate trench portion 40 (second emitter region) are provided in the mesa portion 71 between the neighboring gate trench portions 40. The resistance portion 95 provided to be in contact with the first emitter region is spaced apart from the other gate trench portion 40 and the resistance portion 95 provided to be in contact with the first emitter region is spaced apart from one gate trench portion 40. Then, the contact region 15 is provided in a region which includes a region below the resistance portion 95 provided to be in contact with the first emitter region and a region below the resistance portion 95 provided to be in contact with the second emitter region. Also, in the trench extending direction of the gate trench portion 40, the first emitter region and the second emitter region are provided alternately sandwiching the contact region 15.

FIG. 7B illustrates an example of the j-j′ cross sectional view in FIG. 7A. The semiconductor device 100 in the present example includes the contact trench portion 60 shallower than the emitter region 12 and the resistance portion 95, and the resistance portion 95 provided at both ends of the contact trench portion 60 in the trench arrangement direction, but not limited thereto. That is, the semiconductor device 100 may include the contact trench portion 60 deeper than the emitter region 12 and the resistance portion 95 or may include the resistance portion 95 provided at only one side of the contact trench portion 60.

Note that, although not illustrated in FIG. 7B, the contact region 15 is spaced apart from the gate trench portion 40 in a region in which the emitter region and the resistance portion 95 are provided in the mesa portion 71 between the gate trench portion 40 and the dummy trench portion 30, similarly to FIG. 1A to FIG. 6B.

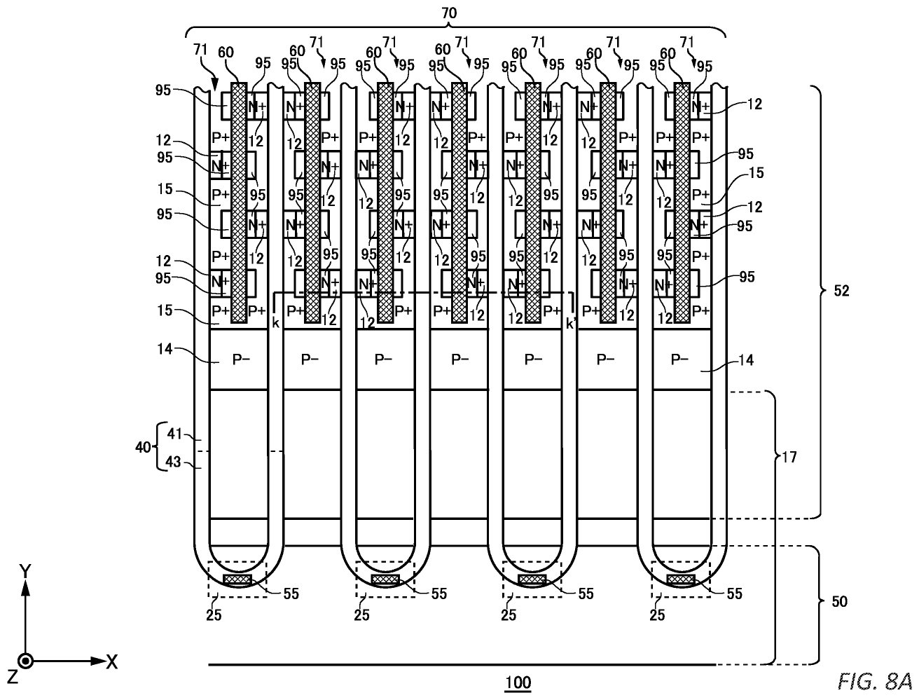

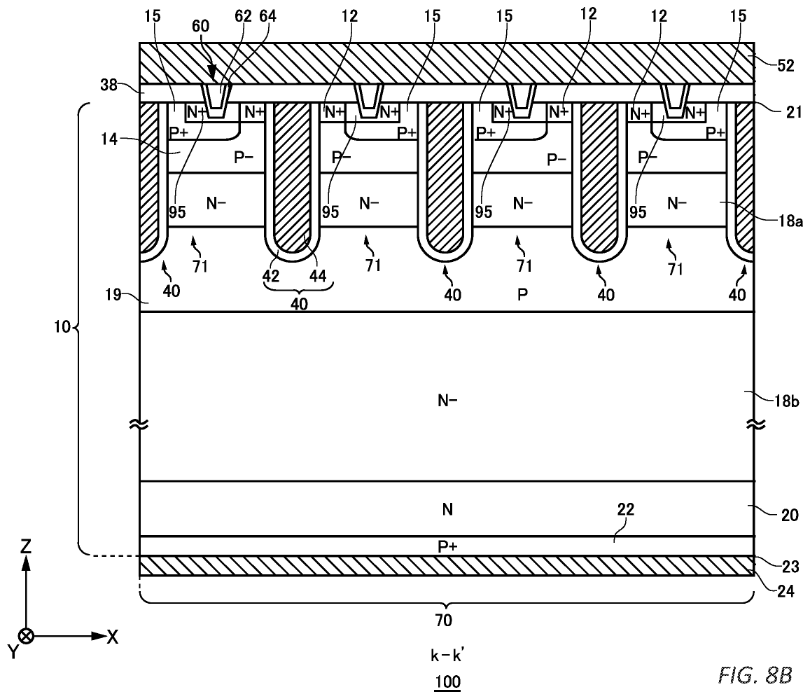

FIG. 8A illustrates an example of the top view of the semiconductor device 100. The semiconductor device 100 in the present example is different from the embodiment in FIG. 7A in the point of providing only the gate trench portion 40 without providing the dummy trench portion 30. The semiconductor device 100 in the present example has a staggered structure with which the emitter regions 12 are arranged alternately, similarly to the embodiment in FIG. 7A. The semiconductor device 100 in the present example has a greater ratio of the emitter region 12 in the front surface 21 than the embodiment in FIG. 7A. Even if the semiconductor device 100 in the present example has a greater ratio of the emitter region 12 in the front surface 21, since a part of the emitter regions 12 are spaced apart from the gate trench portion 40, the latch-up of the semiconductor device 100 can be suppressed.

FIG. 8B illustrates an example of the k-k′ cross sectional view in FIG. 8A. The semiconductor device 100 in the present example includes the contact trench portion 60 shallower than the emitter region 12 and the resistance portion 95, and the resistance portions 95 provided at both ends of the contact trench portion 60 in the trench arrangement direction, but not limited thereto. The resistance portions 95 in the present example are provided with the gate trench portion 40 interposed therebetween at both ends thereof in the trench arrangement direction. In this case, the emitter region 12 and the resistance portion 95 adjacent to each other with the gate trench portion 40 interposed therebetween are patterned collectively such that the reliability of the process can be ensured even when the mesa width is smaller.

While the present invention has been described with the embodiments, the technical scope of the present invention is not limited to the above-described embodiments. It is apparent to persons skilled in the art that various alterations and improvements can be added to the above-described embodiments. It is also apparent from the scope of the claims that the embodiments added with such alterations or improvements can be included in the technical scope of the present invention.

Note that the operations, procedures, steps, and stages of each process performed by an device, system, program, and method shown in the claims, embodiments, or diagrams can be performed in any order as long as the order is not indicated by “prior to,” “before,” or the like and as long as the output from a previous process is not used in a later process. Even if the operation flow is described by using phrases such as “first” or “next” in the scope of the claims, specification, or drawings, it does not necessarily mean that the process must be performed in this order.

### EXPLANATION OF REFERENCES

10: semiconductor substrate, 12: emitter region, 14: base region, 15: contact region, 17: well region, 18: drift region, 19: plug region, 20: buffer region, 21: front surface, 22: collector region, 23: back surface, 24: collector electrode, 25: connection portion, 30: dummy trench portion, 31: extending portion, 32: dummy dielectric film, 33: connection portion, 34: dummy conductive portion 38: interlayer dielectric film, 40: gate trench portion, 41: extending portion, 42: gate dielectric film, 43: connection portion, 44: gate conductive portion, 50: gate metal layer, 52: emitter electrode, 54: contact hole, 55: contact hole, 56: contact hole, 60: contact trench portion, 62: plug, 64: barrier metal layer, 70: transistor portion, 71: mesa portion, 80: diode portion, 81: mesa portion, 82: cathode region, 92: surface region, 94: lower region, 95: resistance portion, 100: semiconductor device.

What is claimed is:

1. A semiconductor device comprising:
a gate trench portion provided in a semiconductor substrate;
a first trench portion provided in the semiconductor substrate and adjacent to the gate trench portion;
an emitter region of a first conductivity type provided to be in contact with the gate trench portion in a mesa portion between the gate trench portion and the first trench portion;
a contact region of a second conductivity type provided to be in contact with the first trench portion in the mesa portion;
a metal layer provided above the semiconductor substrate; and
a resistance portion of the first conductivity type provided to be in contact with the metal layer and the emitter region and having a lower doping concentration than that of the emitter region.

2. The semiconductor device according to claim 1, wherein a doping concentration of the resistance portion is equal to or greater than 5E17 cm⁻³ and equal to or smaller than 2E18 cm⁻³.

3. The semiconductor device according to claim 1, wherein the resistance portion is provided to be in contact with the contact region.

4. The semiconductor device according to claim 2, wherein the resistance portion is provided to be in contact with the contact region.

5. The semiconductor device according to claim 3, wherein the resistance portion has a side wall provided to be in contact with the emitter region and a lower end provided to be in contact with the contact region.

6. The semiconductor device according to claim 1, wherein a width of the resistance portion in a trench arrangement direction is 5 to 25% of a width of the mesa portion.

7. The semiconductor device according to claim 1, wherein the resistance portion is provided to be in contact with a contact hole provided between the metal layer and a front surface of the semiconductor substrate.

8. The semiconductor device according to claim 1, wherein the contact region is provided to extend beyond a contact hole provided between the metal layer and a front surface of the semiconductor substrate from the first trench portion in a trench arrangement direction.

9. The semiconductor device according to claim 1, wherein the contact region is separated from the gate trench portion by 0.1 μm or more in a trench arrangement direction.

10. The semiconductor device according to claim 1, wherein the resistance portion includes a region having a doping concentration increasing from an end of the first trench portion side toward an end of the gate trench portion side in the trench arrangement direction.

11. The semiconductor device according to claim 1, wherein the resistance portion is in contact with the first trench portion at a front surface of the semiconductor substrate.

12. The semiconductor device according to claim 1, wherein the resistance portion is provided to be interposed between the emitter region and the contact region in a trench arrangement direction.

13. The semiconductor device according to claim 1 further comprising a contact trench portion in the mesa portion provided to extend in a depth direction from a front surface of the semiconductor substrate.

14. The semiconductor device according to claim 13, wherein a lower end of the contact region is deeper than a lower end of the contact trench portion.

15. The semiconductor device according to claim 1, wherein the first trench portion is a dummy trench portion set at an emitter potential.

16. The semiconductor device according to claim 1, wherein the first trench portion includes a dummy gate trench portion set at a gate potential and being not in contact with the emitter region.

17. The semiconductor device according to claim 1, wherein the first trench portion is a gate trench portion set at a gate potential.

18. The semiconductor device according to claim 17, wherein
the emitter region includes a first emitter region provided to be in contact with the gate trench portion in the mesa portion, and the resistance portion provided to be in contact with the first emitter region is spaced apart from the first trench portion, and
the contact region is provided below the resistance portion provided to be in contact with the first emitter region in the mesa portion.

19. The semiconductor device according to claim 18, wherein
the emitter region includes a second emitter region provided to be in contact with the first trench portion in the mesa portion, and the resistance portion provided to be in contact with the second emitter region is spaced apart from the gate trench portion, and
the contact region is further provided below the resistance portion provided to be in contact with the second emitter region in the mesa portion.

20. The semiconductor device according to claim 19, wherein the first emitter regions and the second emitter regions are alternately provided in a trench extending direction of the gate trench portion.
